(19) United States
(12) Patent Application Publication
(10) Pub. No.: US 2010/0253363 A1
(43) Pub. Date: Oct. 7, 2010

(54) Method and system for cable detection

(75) Inventor: Jerome Garez, Le Rouret (FR)

Correspondence Address: FARJAMI & FARJAMI LLP, 26522 LA ALAMEDA AVE., SUITE 360, MISSION VIEJO, CA, 92691, US

(73) Assignee: MINDSPEED TECHNOLOGIES, INC., NEWPORT BEACH, CA (US)

(21) Appl. No.: 12/661,348

(22) Filed: Mar. 15, 2010

Related U.S. Application Data
(60) Provisional application No. 61/211,882, filed on Apr. 3, 2009.

(51) Int. Cl. G01R 31/02

(52) U.S. Cl. 324/538

(57) ABSTRACT

There are provided systems and methods for cable detection, such as a video cable. There is provided a device including an output stage, a comparator, a reference selector, a peak detector, and logic gates, which may be arranged to optimize power consumption of the output stage while the cable is unplugged. A method is also provided for such a device, the method comprising detecting whether the cable is unplugged using a cable detector after a first duration of time, turning off the output stage for a second duration of time in response to the cable detector detecting the cable is unplugged, turning on the output stage after the second duration of time, and proceeding to transmit data if the cable detector detects the cable is plugged in for a third period of time, or otherwise repeating the detection, turning off, and turning on steps.

### RELATED APPLICATIONS

This application claims priority to U.S. Provisional Application No. 61/211,882, filed Apr. 3, 2009, which is hereby incorporated by reference in its entirety.

### BACKGROUND OF THE INVENTION

1. Field of the Invention

The present invention is generally in the field of electrical circuits. More specifically, the present invention is in the field of cable detection circuits.

2. Background Art

Optimizing the power efficiency of electrical devices provides several advantages such as reduced operational costs and reduced thermal dissipation requirements. In particular, it is desirable to optimize power consumption when portions of the electrical device are idle or not in use. One such situation is where a cable driver output is connected to a port that has no cable connection to another device. For example, audio/visual equipment may include several output ports for the transmission of data, such as audio or video to other devices, but some of these output ports may not be connected. It is inefficient to power the cable driver output for these unused and disconnected ports. Thus, it is desirable to provide cable detection capabilities for the electrical device so that driver outputs for unused ports can be disabled for energy efficiency.

Conventionally, cable connection status is detected by periodically sending a clock signal to the cable driver output. The cable driver output may be then disabled if the cable connection status is determined as disconnected. However, this approach generally requires an external component for generating the clock signal and a time delay to periodically wake-up the cable driver output. This undesirably increases the cost and complexity of the electrical device.

Accordingly, there is a need in the art for providing cable detection in a simplified and cost efficient manner.

### SUMMARY OF THE INVENTION

There are provided systems and methods for cable detection, such as a video cable, substantially as shown in and/or described in connection with at least one of the figures, as set forth more completely in the claims.

### BRIEF DESCRIPTION OF THE DRAWINGS

The features and advantages of the present invention will become more readily apparent to those ordinarily skilled in the art after reviewing the following detailed description and accompanying drawings, wherein:

FIG. 1 illustrates a diagram of a cable driver system having cable driver output stage and cable detector, according to one embodiment of the present invention;

FIG. 2 illustrates a flowchart describing an operation of the cable driver system of FIG. 1, according to one embodiment of the present invention; and

FIG. 3 illustrates a graph having peak detect curve and reference voltage curve for the cable driver system, according to one embodiment of the present invention.

### DETAILED DESCRIPTION OF THE INVENTION

Although the invention is described with respect to specific embodiments, the principles of the invention can obviously be applied beyond the specifically described embodiments of the invention described herein. Moreover, in the description of the present invention, certain details have been left out to not obscure the inventive aspects of the invention. The details left out are within the knowledge of a person of ordinary skill in the art. The drawings in the present application and their accompanying detailed description are directed to merely example embodiments of the invention. To maintain brevity, other embodiments of the invention which use the principles of the present invention are not specifically described in the present application and are not specifically illustrated by the present drawings.

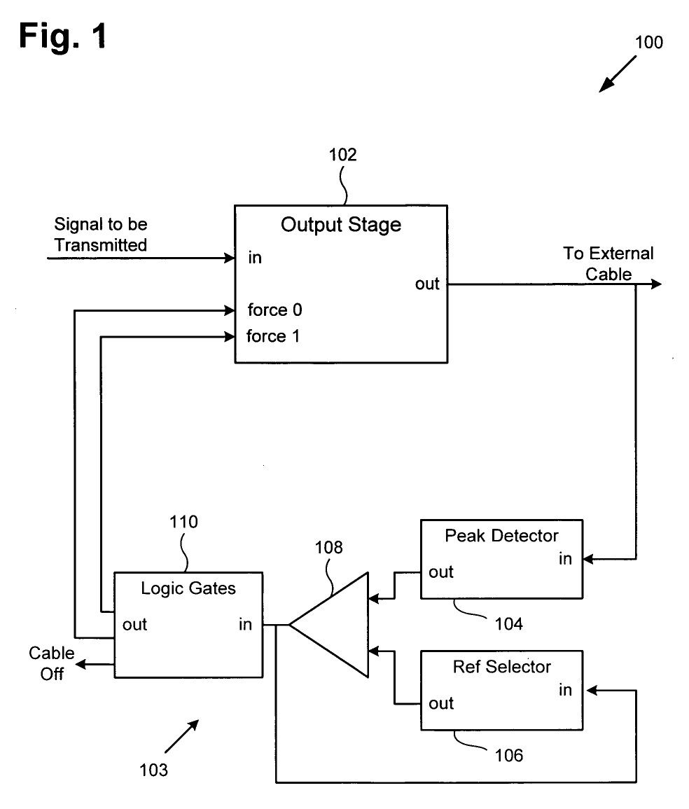

FIG. 1 shows a diagram of cable driver system 100 having cable driver output stage 102 and cable detector 103, according to one embodiment of the present invention. Cable driver system 100 includes cable driver output stage 102 (hereinafter referred to simply as “output stage 102” in the patent application) having an input for receiving data to be transmitted on an output that can be coupled to an external cable, and cable detector 103, which includes peak detector 104, reference voltage selector 106, comparator 108, and logic gates 110. In an embodiment of the present invention, cable detector 103 can be configured to detect when a cable, such as a video cable, is disconnected at the output of output stage 102 and to detect when the cable is reconnected at the output of output stage 102. Cable detector 103 can be further configured to power down output stage 102 for a substantial amount of the time during which the cable is disconnected and to power up output stage 102 when the cable is reconnected. For example, cable detector 103 can reduce the power consumption of output stage 102 by approximately 95 percent when during the time when the cable is disconnected.

With reference to FIG. 1, output of peak detector 104 is coupled to the positive (non-inverting) input of comparator 108, and output of reference voltage selector 106 is coupled to the negative (inverting) input of comparator 108. Comparator 108 switches to a logic high (i.e. a “1”) to detect that the cable has been disconnected. The time period of approximately 100 nanoseconds represents the time required for peak detector 104 to increase to a level greater than the reference voltage. In another embodiment, the time required for peak detector 104 to increase to a level greater than the reference voltage can be greater or less than approximately 100 nanoseconds. As shown in FIG. 1, input of peak detector 104 is coupled to a connector for the external cable, and input of reference voltage selector 106 is coupled to the output of comparator 108.

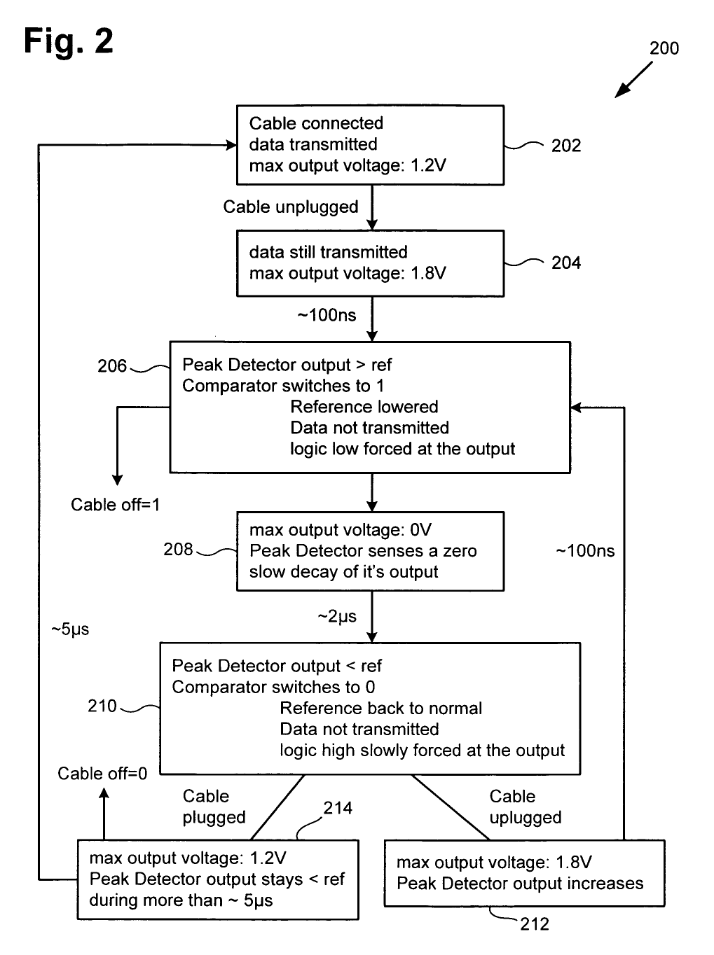

The output of comparator 108 is also coupled to logic gates 110, which has outputs coupled to inputs of output stage 102 for forcing the output of output stage 102 to logic low or logic high, as described in conjunction with FIG. 2 below. Logic gates 110 also includes an output indicating whether the cable has been disconnected or not.

The operation of cable detector 103 and output stage 102 will be discussed in reference to flowchart 200 in FIG. 2. At step 202 of flowchart 200, a cable, such as a video cable, is connected to the output of output stage 102 and data is being transmitted by output stage 102 in a normal operating mode. The maximum output voltage at the output of output stage 102 can be approximately 1.2 volts, for example. At step 204, the cable has been disconnected from output stage 102 and data is still being transmitted by the output stage. The maximum output voltage at output stage 102 can be, for example, approximately 1.8 volts when the cable has been disconnected.

At step 206, after a time period of, for example, approximately 100 nanoseconds (ns), the output of peak detector 104, which is coupled to the positive (non-inverting) input of comparator 108, is greater than a reference voltage (i.e. a threshold voltage), which can be, for example, approximately 1.4 volts, and comparator 108 switches to a logic high (i.e. a “1”) to detect that the cable has been disconnected. The time period of approximately 100 nanoseconds represents the time required for peak detector 104 to increase to a level greater than the reference voltage. In another embodiment, the time required for peak detector 104 to increase to a level greater than the reference voltage can be greater or less than approximately 100 nanoseconds.

The reference voltage can be provided by reference voltage selector 106, which has an input coupled to the output of comparator 108 and an output coupled to the negative (inverting) input of comparator 108. The reference voltage provided by reference voltage selector 106 can be lowered to, for example, approximately 1.3 volts to magnify hysteresis when detection of the disconnected cable has occurred. This increases the time until cable detector 103 checks to see if a cable has been connected to the output of output stage 102 by increasing the decay time of the peak detected voltage store in memory in peak detector 104. A logic low is forced at the output of output stage 102 via logic gates 110, which is coupled between the output of comparator 108 and output stage 102, and output stage 102 is turned off, thereby reducing power consumption.

At step 208, since output stage 102 has been turned off at step 206, the maximum output voltage at output stage 102 can be approximately 0.0 volts. Peak detector 104 senses the approximately 0.0 volt output of output stage 102 and the output of peak detector 104 slowly decays. The slow decay of the output of peak detector 104 occurs because the peak voltage that is stored in memory in peak detector 104 slowly decreases over time.

At step 210, after a predetermined time period has expired, which can be, for example, approximately 2.0 microseconds (μs), the output of peak detector 104 has decayed to a level that is less than the reference voltage of approximately 1.3 volts provided by reference voltage selector 106. In another embodiment, the time period required for the output of peak detector 104 to decay below the reference voltage can be less than or greater than approximately 2.0 microseconds. As a result, the output of comparator 108 switches to a logic low (i.e. “0”) and reference voltage selector 106 provides a higher reference voltage of approximately 1.4 volts to the negative input of comparator 108. At this point, data is not being transmitted by output stage 102, which has been turned off during the predetermined time period of approximately 2.0 microseconds. A logic high is slowly forced at the output of output stage 102 by logic gates 110, which receives the logic low output of comparator 108, and output stage 102 is turned on. If the cable remains unplugged, output stage 102 will output a maximum voltage of, for example, approximately 1.8 volts, since there is no load on output stage 102. If the cable is plugged into output stage 102, output stage 102 will output a maximum voltage of, for example, approximately 1.2 volts. If the cable is not plugged into output stage 102, flowchart 200 proceeds to step 212; and if the cable is plugged into output stage 102, flowchart 200 proceeds to step 214.

At step 212, if the cable is not plugged into output stage 102, peak detector 104 receives a peak voltage of approximately 1.8 volts from output stage 102 and the output of peak detector 104 increases. The approximately 1.8 volts received from output stage 102 is interpreted as a cable off condition. Flowchart 200 proceeds back to step 206.

At step 214, if the cable is plugged into output stage 102, peak detector 104 receives a peak voltage of approximately 1.2 volts from output stage 102. The approximately 1.2 volts received from output stage 102 is interpreted as a cable on condition. As a result of the approximately 1.2 volts received from output stage 102, the output of peak detector 104 remains less than the reference voltage provided by reference voltage selector 106. If the output of peak detector 104 remains less than the reference voltage provided by reference voltage selector 106 for a window time period of approximately 5.0 microseconds, the cable on condition is verified and flowchart 200 proceeds back to step 202. If, during the window time period, the output of peak detector 104 increases above the reference voltage, a cable off condition is indicated and flowchart 200 proceeds to step 206. In another embodiment, the window time period can be less than or greater than approximately 5.0 microseconds.

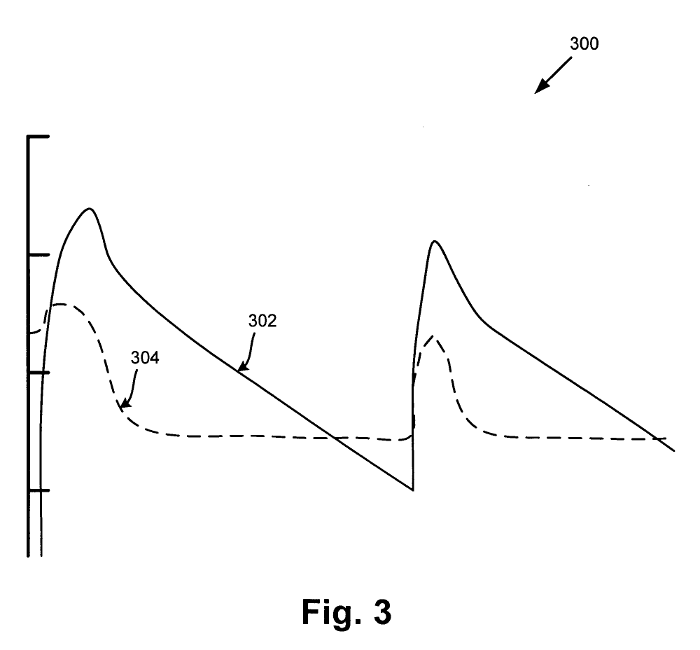

FIG. 3 shows graph 300 according to one embodiment of the present invention. Graph 300 includes peak detect curve 302 and reference voltage curve 304. As shown in graph 300, peak detect curve 302 quickly rises to detect a peak voltage and slowly decays when the cable is unplugged from output stage 102 and there is no peak voltage to detect. Reference voltage curve 304 goes from approximately 1.4 volts when the cable is plugged into output stage 102 to approximately 1.3 volts when the cable is unplugged.

Thus, in an embodiment of the present invention, when a cable is unplugged from output stage 102, for a time period of approximately 100 nanoseconds, output stage 102 is turned on while cable detector 103 determines if the cable has been plugged in. If the cable has not been plugged in, output stage 102 is turned off for a time period of approximately 2.0 microseconds. After the time period of approximately 2.0 microseconds has expired, output stage 102 is turned on again for a time period of approximately 100 nanoseconds while cable detector 103 determines if the cable has been plugged in. The cycle discussed above can be repeated until the cable is plugged into output stage 102. Thus, an embodiment of the present invention's cable detector 103 can substantially reduce the power consumption of output stage 102 by turning output stage 102 off for a substantial portion of the time during which the cable is unplugged from output stage 102. For example, since according to one embodiment of the present invention, output stage 102 is only turned on about five percent of the time while the cable is disconnected, or 100 nanoseconds on for every 2 microseconds (2000 nanoseconds) off, a device integrating the described power stage can reduce power consumption by about 95% compared to a device with an always on power stage. By adjusting these time ratios within the limits imposed by peak detect curve 302 and reference voltage curve 304, even greater savings in power consumption can be achieved.

From the above description of the invention it is manifest that various techniques can be used for implementing the concepts of the present invention without departing from its scope. Moreover, while the invention has been described with specific reference to certain embodiments, a person of ordinary skills in the art would recognize that changes can be made in form and detail without departing from the spirit and the scope of the invention. As such, the described embodiments are to be considered in all respects as illustrative and not restrictive. It should also be understood that the invention is not limited to the particular embodiments described herein, but is capable of many rearrangements, modifications, and substitutions without departing from the scope of the invention.

What is claimed is:

1. A device configured to receive a cable and being capable of detecting that the cable is unplugged from the device, the device comprising:
an output stage;
a cable detector configured to detect, after the cable is unplugged for a first duration of time, whether the cable is unplugged from the device while the output stage remains turned on;
wherein the output stage is further configured to be turned off after the first duration of time, for a second duration of time, in response to the cable detector detecting that the cable was unplugged from the device while the output stage remains turned on; and
wherein the output stage is further configured to be turned on after expiration of the second duration of time and to transmit data through the cable in response to the cable detector detecting that the cable is plugged into the device for a third duration of time.

2. The device of claim 1, wherein the cable is a video cable, the data comprises video data, and the cable detector is a video cable detector.

3. The device of claim 1, wherein the cable detector includes:
a comparator having a first input, a second input and an output;
a peak detector having an input coupled to an output of the output stage capable of receiving the cable, and an output coupled the first input of the comparator;
a reference voltage selector having an input coupled to the output of the comparator, and an output coupled the second input of the comparator; and
logic gates having an input coupled to the output of the comparator, and a first output coupled the output stage for forcing the output stage on or off.

4. The device of claim 3, wherein the logic gate further includes a second output indicative of the cable being plugged in or unplugged.

5. The device of claim 3, wherein the first input of the comparator comprises a positive (non-inverting) input, and wherein the second input of the comparator comprises a negative (inverting) input.

6. The device of claim 3, wherein the output stage is configured to output a first maximum voltage of approximately 1.2 volts when the cable is connected and a second maximum voltage of approximately 1.8 volts when the cable is disconnected, and wherein the reference voltage selector is configured to provide voltages between said first maximum voltage and said second maximum voltage.

7. The device of claim 3, wherein the reference voltage selector is configured to provide approximately 1.4 volts when the cable detector detects the cable is plugged into the device and to provide approximately 1.3 volts when the cable detector detects the cable is unplugged from the device.

8. The device of claim 1, wherein the first duration of time is approximately five percent or less of the second duration of time, thereby reducing power consumption of the output stage during the time when the cable is disconnected from the device by approximately 95 percent or more compared to when the output stage is always on.

9. The device of claim 8, wherein the first duration of time is approximately 100 nanoseconds, and wherein the second duration of time is approximately 2 microseconds (2000 nanoseconds).

10. The device of claim 1, wherein the third duration of time is approximately 5 microseconds (5000 nanoseconds).

11. A method of detecting a cable connection to a device configured to receive the cable, the method comprising:
detecting, using a cable detector, whether the cable is unplugged from the device while an output stage of the device remains turned on and after the cable is unplugged from the device for a first duration of time;
turning off the output stage for a second duration of time after the first duration of time in response to the cable detector detecting that the cable was unplugged from the device while the output stage remains turned on;
turning on the output stage after expiration of the second duration of time; and
transmitting data through the cable in response to the cable detector detecting that the cable is plugged into the device for a third duration of time, or repeating the turning off and turning on in response to the cable detector detecting that the cable is unplugged from the device after an elapsing of time equal to at least the first duration of time.

12. The method of claim 11, wherein the cable is a video cable, the data is video data, and the cable detector is a video cable detector.

13. The method of claim 11, wherein the detecting includes:
detecting a peak voltage at an output of the output stage capable of receiving the cable;
comparing the peak voltage with a reference voltage to generate a comparison signal;
forcing the output stage on or off based on the comparison signal.

14. The method of claim 13 further comprising:
determining the reference voltage using the comparison signal.

15. The method of claim 13, wherein the comparing is performed by a comparator having a first input including a positive (non-inverting) input, and a second input including a negative (inverting) input.

16. The method of claim 13, wherein the output stage is configured to output a first maximum voltage of approximately 1.2 volts when the cable is connected and a second maximum voltage of approximately 1.8 volts when the cable is disconnected, and wherein the reference voltage is between said first maximum voltage and said second maximum voltage.

17. The method of claim 13, wherein the reference voltage is approximately 1.4 volts when the cable detector detects the cable is plugged into the device and is approximately 1.3 volts when the cable detector detects the cable is unplugged from the device.

18. The method of claim 11, wherein the first duration of time is approximately five percent or less of the second duration of time, thereby reducing power consumption of the output stage during the time when the cable is disconnected from the device by approximately 95 percent or more compared to when the output stage is always on.

19. The method of claim 18, wherein the first duration of time is approximately 100 nanoseconds, and wherein the second duration of time is approximately 2 microseconds (2000 nanoseconds).

20. The method of claim 11, wherein the third duration of time is approximately 5 microseconds (5000 nanoseconds).
